(19) United States
(12) Patent Application Publication
(10) Pub. No.: US 2010/0232228 A1
(43) Pub. Date: Sep. 16, 2010

(54) MEMORY DEVICE, MEMORY SYSTEM AND PROGRAMMING METHOD

(75) Inventors: Hong Soo JEON, Hwasung-si (KR); Ji-Sang LEE, Iksan-si (KR); Oh Suk KWON, Yongin-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/715,692

(22) Filed: Mar. 2, 2010

(30) Foreign Application Priority Data
Mar. 10, 2009 (KR) 10-2009-0020172

(51) Int. Cl. G11C 16/04; G11C 16/06

(52) U.S. Cl. 365/185.19; 365/185.22

(57) ABSTRACT

A method of programming a memory device includes comparing a first verify voltage and a distribution voltage of at least one memory cell, and if a result of the comparison is a pass, adjusting the distribution voltage until the distribution voltage is higher than a second verify voltage while comparing the distribution voltage and the second verify voltage.

### CROSS-REFERENCE TO RELATED APPLICATIONS

This application claims priority under 35 U.S.C. §119 to Korean Patent Application No. 10-2009-0020172 filed on Mar. 10, 2009, the subject matter of which is hereby incorporated by reference

### BACKGROUND

The inventive concept relates to memory devices, and more particularly, to a method of programming a memory device.

Flash memory is one form of non-volatile memory capable of performing electrical program and erase operations. Flash memory is widely used in consumer electronics and most notably in mobile devices where its small size per unit data storage capacity and relatively high data access speed make it an excellent choice to store both programming code and user (or payload) data. Contemporary flash memory may be classified as NAND type flash or NOR type flash.

The data stored in a flash memory device is defined by a memory cell threshold voltage or distribution voltage. A program operation is used to define the threshold voltage of a memory cell according to a corresponding data state. In general, the threshold voltage of a memory cell being defined during a program operation may be controlled using the conventionally understood incremental step pulse program (ISPP) method. According to the ISPP method, a program operation directed to a selected memory cell(s) may be performed using certain control voltages, at least one of which (e.g., a voltage applied to the word line connected to the selected memory cell) is gradually changed (increased or decreased) according to a voltage step constant. The threshold voltages(s) of non-selected cells around the selected memory cell(s) (i.e., neighboring memory cells having previously been programmed) may be unintentionally affected by the application of an increasing ISPP control voltage. At some point, the data stored in the neighboring memory cell(s) may be altered by the proximate application of a relatively high program voltage to the selected memory cell(s).

Recognizing this undesirable outcome, a 2-step verify program voltage approach has recently been proposed to better ensure appropriate distribution voltages (or threshold voltages) for neighboring memory cells following programming of selected memory cell(s). Unfortunately, some additional operating time is required to execute a program operation within a flash memory device including this type of enhanced verify program voltage approach.

### SUMMARY

The inventive concept provides a method for programming a memory device which may better optimize a distribution voltage, and a memory device using the method.

According to an aspect of the inventive concept, there is provided a method of programming a memory device which includes a first verify operation in which a first verify voltage is compared with a distribution voltage of a memory cell, and a second verify operation in which if a result of the comparison performed in the first verify operation is pass, the distribution voltage is adjusted until the distribution voltage is higher than a second verify voltage.

In a related aspect, the second verify operation may include comparing the distribution voltage and the second verify voltage while adjusting the distribution voltage to be higher than the second verify voltage.

In another related aspect, the method further includes adjusting the distribution voltage using a first program voltage if the comparison result of the first verify operation is fail, wherein the adjusting the distribution voltage is repeatedly performed until the distribution voltage is higher than the first verify voltage.

In another related aspect, adjusting the distribution voltage using the first program voltage may be performed according to an incremental step pulse program (ISPP) method in which the first program voltage is applied to a word line connected to the memory cell.

In another related aspect, the second verify operation includes; comparing the distribution voltage and the second verify voltage, and adjusting the distribution voltage using a second program voltage, if a comparison result of the second verify operation is fail, wherein the adjusting the distribution voltage is repeatedly performed until the adjusted distribution voltage is higher than the second verify voltage.

In still another related aspect, adjusting of the distribution voltage using the second program voltage may be performed by a bit line forcing method in which the second program voltage is applied to a bit line connected to the at least one memory cell.

In another aspect of the inventive concept, a method of programming a memory device is provided and includes; comparing a first verify voltage and a distribution voltage of a memory cell to generate a comparison result, and if the comparison result is fail, adjusting the distribution voltage using a first program voltage until the distribution voltage is higher than a first verify voltage, and if the comparison result is pass, adjusting the distribution voltage using a second program voltage until the distribution voltage is higher than a second verify voltage.

In another aspect of the inventive concept, a memory system includes; a card interface, a slot connected to the card interface, wherein the slot is configured to mechanically accept and electrically connect a memory device, wherein the memory device comprises; a cell array comprising a memory cell, a comparator configured to compare at least one verify voltage and a distribution voltage of the memory cell and providing a comparison result, a controller configured to provide a control signal in response to the comparison result, and a voltage generator configured to provide a first program voltage and a second program voltage to the cell array in response to the control signal, wherein the cell array adjusts the distribution voltage of the memory cell according to either the first program voltage or the second program voltage.

### BRIEF DESCRIPTION OF THE DRAWINGS

Embodiments of the inventive concept will be more clearly understood from the following detailed description taken in conjunction with the accompanying drawings in which:

FIG. 1 is a schematic block diagram of a memory device according to an embodiment of the inventive concept;

FIG. 2 is a flowchart summarizing a method of programming the memory device of FIG. 1;

FIG. 3 (inclusive of FIGS. 3A-3C) and FIG. 4 (inclusive of FIGS. 4A-4D) are conceptual memory cell distribution diagrams according to a variety of conditions possibly existing in certain embodiments of the invention during application of the method of FIG. 2;

FIG. 5 is a block diagram of a memory system susceptible to the incorporation of a memory device according to an embodiment of the inventive concept; and

FIG. 6 (inclusive of FIGS. 6A-6J) illustrates a variety of embodiments for various memory systems including a memory device according to an embodiment of the inventive concept.

### DETAILED DESCRIPTION OF EMBODIMENTS

The attached drawings for illustrating embodiments of the inventive concept are referred to in order to gain a sufficient understanding of the inventive concept and the merits thereof. Hereinafter, the inventive concept will be described in some additional detail with reference to the attached drawings. However, the inventive concept may be variously embodied and should not be construed as being limited to only the illustrated examples. Throughout the written description and drawings like reference numbers and labels are used to denote like or similar elements.

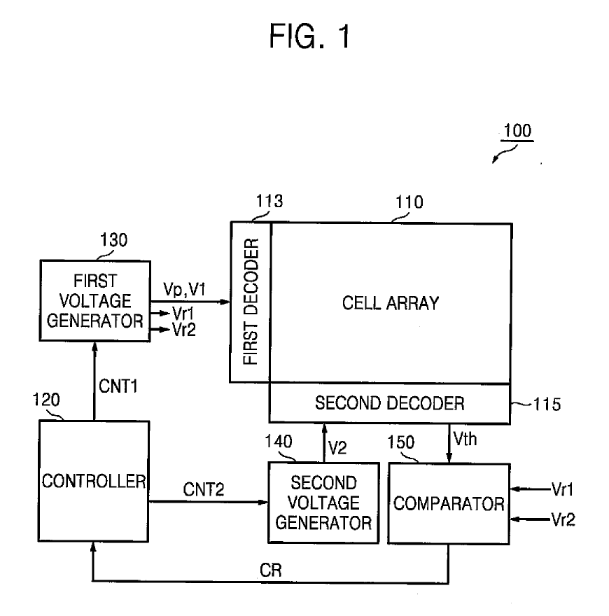

FIG. 1 is a schematic block diagram of a memory device 100 according to an embodiment of the inventive concept. Referring to FIG. 1, the memory device 100 comprises a cell array 110, voltage generators 130 and 140, a comparator 150, and a controller 120.

The memory device 100 may include a row decoder, for example, a first decoder 113, and a column decoder, for example, a second decoder 115. A plurality of memory cells (not shown) may be arranged in the cell array 110 and each of the memory cells may be connected to a bit line (not shown) and a word line (not shown).

The voltage generators 130 and 140 may include a first voltage generator 130 and a second voltage generator 140. The first voltage generator 130 may output a program voltage to the cell array 110 according to a control signal, for example, a first control signal CNT1, provided from the controller 120 that will be described later. The first voltage generator 130 may output a first program voltage V1, for example, a word line application voltage, according to the first control signal CNT1. The first program voltage V1 output from the first voltage generator 130 may be provided to each of a plurality of word lines to which a plurality of memory cells of the cell array 110 are respectively connected, via the first decoder 113. Each of the memory cells may control a threshold voltage or a distribution voltage Vth of each of the memory cells by using the first program voltage V1.

The first voltage generator 130 may output an initial program voltage Vp, a first verify voltage Vr1, and a second verify voltage Vr2, in addition to the first program voltage V1, to the cell array 110 via the first decoder 113.

The second voltage generator 140 may output a program voltage to the cell array 110 according to a control signal, for example, a second control signal CNT2, provided by the controller 120. The second voltage generator 140 may output a second program voltage V2, for example, a bit line application voltage, according to the second control signal CNT2. The second program voltage V2 output from the second voltage generator 140 may be provided to each of a plurality of bit lines to which the memory cells of the cell array 110 are respectively connected, via the second decoder 115. Each of the memory cells may control the threshold voltage or distribution voltage Vth of each of the memory cells by using the second program voltage V2.

The first program voltage V1 output from the first voltage generator 130 may have a higher level than the second program voltage V2 output for the second voltage generator 140. For example, the first program voltage V1 may be provided by an incremental step pulse program (ISPP) method in which a step voltage increasing by large amplitude is provided to the word line of each of the memory cells of the cell array 110. The second program voltage V2 may be provided by a bit line forcing method in which a step voltage increasing by a smaller amplitude than that of the ISPP method is provided to the word line of each of the memory cells of the cell array 110.

The comparator 150 may compare the states of the memory cells sensed from the cell array 110, that is, the distribution voltage Vth of a cell and at least one verify voltage, for example, a first verify voltage Vr1 or a second verify voltage Vr2, and output a comparison result CR. For example, the comparator 150 may sense the distribution voltage Vth of each of the memory cells after the cell array 110 is programmed by the initial program voltage Vp. The comparator 150 may compare the sensed distribution voltage Vth and the first verify voltage Vr1 and output the comparison result CR having a different level, for example, a high level or a low level, according to the comparison. Also, the comparator 150 may compare the sensed distribution voltage Vth and the second verify voltage Vr2 and output the comparison result CR having a different level according to the comparison.

The controller 120 may output at least one control signal from, for example, the first control signal CNT1 and the second control signal CNT2, according to the comparison result CR output from the comparator 150. The output first and second control signals CNT1 and CNT2 may respectively control the operations of the first and second voltage generators 130 and 140. For example, the first control signal CNT1 output from the controller 120 may control the operation of the first voltage generator 130 so that the first voltage generator 130 may output the first program voltage V1. Also, the second control signal CNT2 output from the controller 120 may control the operation of the second voltage generator 140 so that the second voltage generator 140 may output the second program voltage V2.

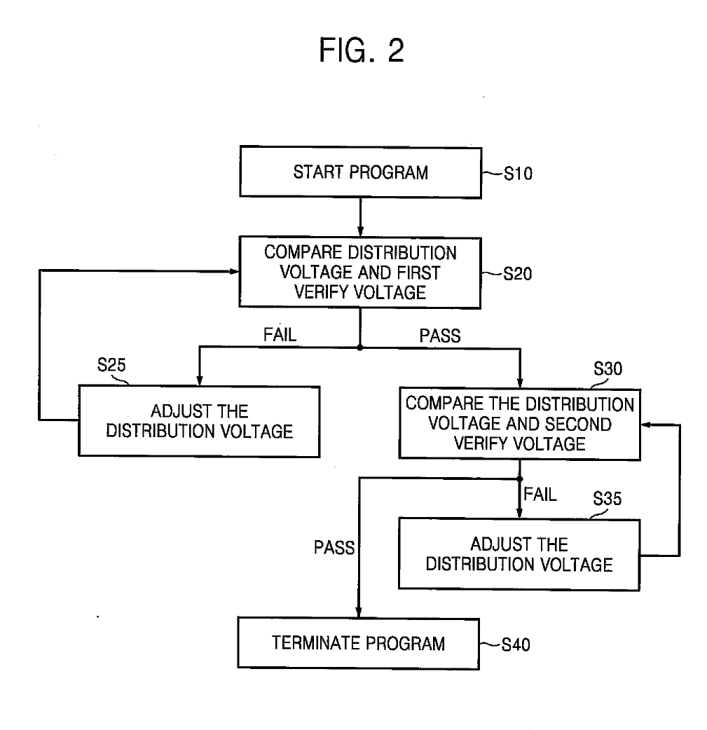

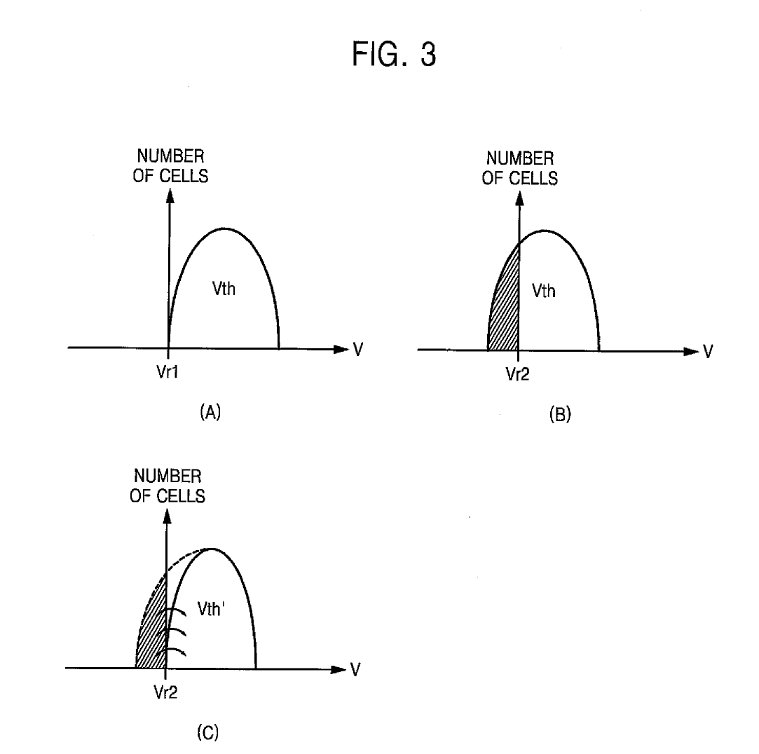

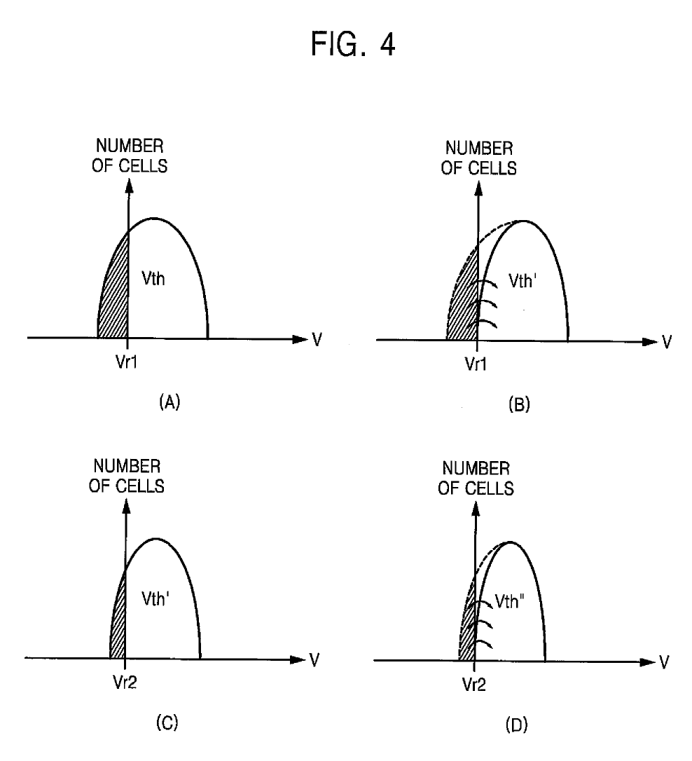

The method of programming the memory device 100 will be described in detail with reference to FIG. 2-4. FIG. 2 is a flowchart for explaining a method of programming the memory device of FIG. 1. FIG. 3 (inclusive of FIGS. 3A-3C) and FIG. 4 (inclusive of FIGS. 4A-4D) are conceptual memory cell distribution diagrams according to a variety of conditions possibly existing in certain embodiments of the invention during application of the method of FIG. 2;

Referring to FIGS. 1 and 2, the first decoder 113 may provide the initial program voltage Vp provided by the first voltage generator 130 to each of the word lines of the cell array 110. Each of the memory cells of the cell array 110 may start a program operation by the initial program voltage Vp provided through the word line (S10).

After the program operation of each of the memory cells is completed, the comparator 150 compares the states of the memory cells of the cell array 110 output from the second decoder 115, that is, the distribution voltage Vth of the cell and the first verify voltage Vr1, and output the comparison result CR (S20). For example, when the comparator 150 outputs a comparison result CR having a first level, for example, a high level, to indicate that the distribution voltage Vth is lower than the first verify voltage Vr1 (hereinafter, referred to as a case in which the cell programmed by the initial program voltage Vp is in a fail state), the controller 120 may output the first control signal CNT1 according to the comparison result CR of the first level.

The first control signal CNT1 output from the controller 120 may be provided to the first voltage generator 130. The first voltage generator 130 may output the first program voltage V1 to the cell array 110 to adjust the distribution of the distribution voltage Vth of a cell (S25).

Although it is not illustrated, an operation of comparing the distribution voltage Vth and the second verify voltage Vr2, (e.g., S30 of FIG. 2) may be further performed between the step of comparing the distribution voltage and the first verify voltage (S20) and the step of adjusting the distribution voltage (S25).

The memory device 100 may repeatedly adjust the distribution of the distribution voltage Vth of a cell using the first program voltage V1 until the distribution voltage Vth is greater than the first verify voltage Vr1. For example, the memory device 100 may first adjust the distribution of the distribution voltage Vth of a cell by using the first program voltage V1 and then repeatedly perform the program operation from the operation S20.

That is, the memory device 100 may adjust the distribution of the distribution voltage Vth of a cell by using the first program voltage V1 until the comparator 150 outputs a comparison result CR having a second level, for example, a low level, to indicate that the distribution voltage Vth adjusted by the first program voltage V1 is higher than the first verify voltage Vr1 (hereinafter, referred to as the case in which the cell in which the distribution voltage Vth is adjusted by the first program voltage V1 is in a pass state).

Also, the first program voltage V1 may be provided to each of the word lines of the cell array 110. The distribution of the distribution voltage Vth of each of the memory cells may be adjusted by the ISPP method.

When the comparator 150 compares the distribution voltage Vth of a cell and the first verify voltage Vr1 (S20) and outputs the comparison result CR of the second level to indicate the pass state in which the distribution voltage Vth is higher than the first verify voltage Vr1, the comparator 150 may compare the distribution voltage Vth of a cell and the second verify voltage Vr2, and output the comparison result CR (S30).

When the comparator 150 outputs the comparison result CR of the second level to indicate the pass state in which the distribution voltage Vth is higher than the second verify voltage Vr2, the memory device 100 may terminate the program operation (S40). However, when the comparator 150 outputs the comparison result CR of the first level to indicate the fail state in which the distribution voltage Vth is lower than the second verify voltage Vr2, the controller 120 may output the second control signal CNT2 according to the comparison result CR.

The second control signal CNT2 output from the controller 120 may be provided to the second voltage generator 140. The second voltage generator 140 may adjust the distribution of the distribution voltage Vth of a cell by outputting the second program voltage V2 to the cell array 110 (S35). The memory device 100 may adjust the distribution of the distribution voltage Vth of a cell by repeating the program operation until the distribution voltage Vth is greater than the second verify voltage Vr2 by using the second program voltage V2.

For example, the memory device 100 may primarily adjust the distribution of the distribution voltage Vth by using the second program voltage V2 and compare the adjusted distribution voltage Vth of a cell and the second verify voltage Vr2 so that the program operation may be repeated from the operation S30.

That is, the memory device 100 may adjust the distribution of the distribution voltage Vth of a cell by using the second program voltage V2 until the comparator 150 outputs the comparison result CR having the second level, for example, a low level, to indicate that the distribution voltage Vth adjusted by the second program voltage V2 is higher than the second verify voltage Vr2.

The second program voltage V2 may be provided to each of the bit lines of the cell array 110. The distribution of the distribution voltage Vth of each of the memory cells may be adjusted by the bit line forcing method.

The method of programming the memory device 100 according to an embodiment of the present inventive concept will be described below with reference to FIGS. 1-3. FIG. 3A illustrates the first verify operation (S20 of FIG. 2) in which the comparator 150 compares the first verify voltage Vr1 and the distribution voltage Vth of at least one memory cell programmed by the initial program voltage Vp. As a result of the comparison by the comparator 150, since the distribution voltage Vth is higher than the first verify voltage Vr1, that is, the at least one memory cell is in the pass state, the comparator 150 may output the comparison result CR of the second level.

FIG. 3B illustrate the second verify operation (S30 of FIG. 2) in which the comparator 150 compares the second verify voltage Vr2 and the distribution voltage Vth of the at least one memory cell programmed by the initial program voltage Vp. The first and second verify voltages Vr1 and vr2 input to the comparator 150 may be voltages having different levels. In the illustrated embodiment, as an example, the second verify voltage Vr2 may be a higher signal than the first verify voltage Vr1.

As a comparison result of the comparator 150, since the distribution voltage Vth is lower than the second verify voltage Vr2, that is, the at least one memory cell is in the fail state, the comparator 150 may output the comparison result CR of the first level.

The controller 120 may output the second control signal CNT2 to the second voltage generator 140 according to the comparison result CR of the first level output from the comparator 150. The second voltage generator 140 may output the second program voltage V2 to the cell array 110 via the second decoder 115 according to the second control signal CNT2.

FIG. 3C illustrate the operation (S35 of FIG. 2) in which at least one memory cell of the cell array 110 adjusts the distribution voltage Vth by using the second program voltage V2 output from the second voltage generator 140. The second program voltage V2 output from the second voltage generator 140 may be provided to the bit lines of the cell array 110 by the bit line forcing method. The distribution voltage Vth of the at least one memory cell may be adjusted to have a small amplitude. Accordingly, the distribution of an adjusted distribution voltage Vth′ of the memory cell may be optimized according to a fixed upper voltage and a lower voltage adjusted to have small amplitude by the bit line forcing method.

The method of programming the memory device 100 according to another embodiment of the present inventive concept will be described below with reference to FIGS. 1, 2, and 4A-4D. FIG. 4A illustrates the first verify operation (S20 of FIG. 2) in which the comparator 150 compares the first verify voltage Vr1 and the distribution voltage Vth of the at least one memory cell that is programmed by the initial program voltage Vp.

As a result of the comparison by the comparator 150, since the distribution voltage Vth is lower than the first verify voltage Vr1, that is, the at least one memory cell is in the fail state, the comparator 150 may output the comparison result CR of the first level. The controller 120 may output the first control signal CNT1 to the first voltage generator 130 according to the comparison result CR of the first level output from the comparator 150. The first voltage generator 130 may output the first program voltage V1 to the first decoder 113 via the cell array 110 according to the first control signal CNT1.

FIG. 4B illustrates the operation (S25 of FIG. 2) in which the at least one memory cell of the cell array 110 adjusts the distribution voltage Vth by using the first program voltage V1 output from the first voltage generator 130. The first program voltage V1 output from the first voltage generator 130 may be provided to the word line of the cell array 110 by the ISPP method. The distribution voltage Vth of the at least one memory cell may be adjusted to have a large amplitude.

FIG. 4C indicates the second verify operation (S30 of FIG. 2) in which the comparator 150 compares the second verify voltage Vr2 and the distribution voltage Vth′ of the at least one memory cell adjusted by the first program voltage V1. As a result of the comparison by the comparator 150, since the distribution voltage Vth′ is smaller than the second verify voltage Vr2, that is, the at least one memory cell is in the fail state, the comparator 150 may output the comparison result CR of the first level.

Accordingly, the controller 120 may output the second control signal CNT2 to the second voltage generator 140 according to the comparison result CR of the first level output from the comparator 150. The second voltage generator 140 may output the second program voltage V2 to the cell array 110 via the second decoder 115 according to the second control signal CNT2.

The FIG. 4D illustrates the operation (S35 of FIG. 2) in which the at least one memory cell of the cell array 110 adjusts again the distribution voltage Vth′ that is already adjusted by the first program voltage V1, by using the second program voltage V2 output from the second voltage generator 140.

The second program voltage V2 output from the second voltage generator 140 may be provided by the bit line forcing method to the bit line of the cell array 110. The distribution voltage Vth' of the at least one memory cell may be adjusted to have a small amplitude. Accordingly, the distribution of a distribution voltage Vth″ of the memory cell that is adjusted may be optimized by an upper end voltage that is fixed and a lower end voltage that is adjusted by the ISPP method and the bit lien forcing method.

As described above, the memory device 100 according to the above-described embodiments may reduce the overall program operation time even when two-time verify operations are performed during the program operation, the distribution characteristic of the distribution voltage Vth of the at least one memory cell may be improved.

Memory devices according to certain embodiments of the inventive concept have been described above. A memory device according to an embodiment of the inventive concept may be, (e.g.,) a NAND flash memory device configured for use according to a variety of packaging techniques.

For example, the NAND flash memory device might be mounted by using a variety of packages such as a package on package (PoP), a ball grid array (BGA), a chip scale package (CSP), a plastic leaded chip carrier (PLCC), a plastic dual in-line package (PDIP), a die in waffle pack, a die in wafer form, a chip on board (COB), a ceramic dual in-line package (CERDIP), a plastic metric quad flat pack (MQFP), a thin quad flat pack (TQFP), a small outline (SOIC), a shrink small outline package (SSOP), a thin small outline (TSOP), a thin quad flat pack (TQFP), a system in package (SIP), a multi chip package (MCP), a wafer-level fabricated package (WFP), and a wafer-level processed stack package (WSP).

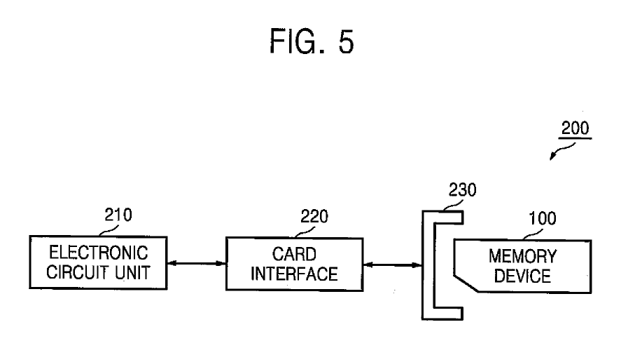

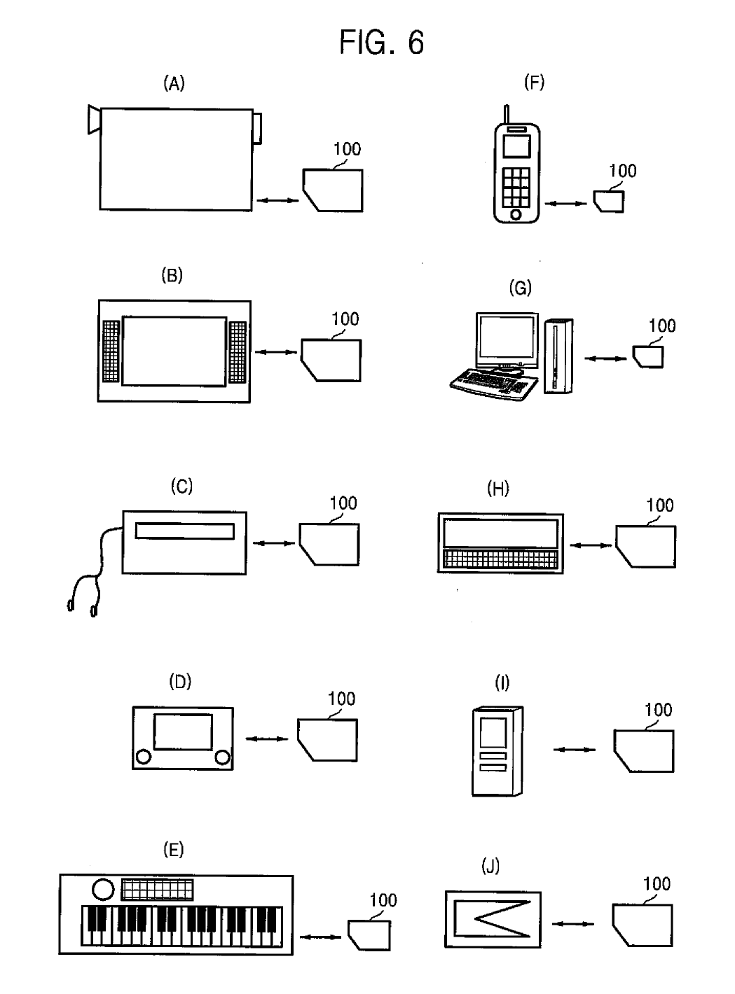

FIG. 5 is a block diagram of a memory system including the memory device of FIG. 1. FIGS. 6A-6J further illustrate a variety of possible system embodiments susceptible to the benefits of certain embodiments of the inventive concept.

Referring collectively to FIGS. 5 and 6A-6J, a memory device according to an embodiment of the inventive concept, such as memory device 100 shown in FIG. 1, may be implemented as a memory card including, for example, a secure digital (SD) card or a multi-media card (MMC). Also, the memory card may be included as a smart card.

The memory card using the memory device 100 may be used for video cameras (FIG. 6A), TVs or IPTVs (FIG. 6B), MP3 players (FIG. 6C), game consoles or navigations (FIG. 6D), electronic instruments (FIG. 6E), portable communication terminals such as mobile telephones (FIG. 6F), personal computers (PCs) (FIG. 6G), personal digital assistants (PDAs) (FIG. 6H), voice recorders (FIG. 6I), or PC cards or memory card readers (FIG. 6J).

Thus, when the video cameras (FIG. 6A), the TVs or IPTVs (FIG. 6B), the MP3 players (FIG. 6C), the game consoles or navigations (FIG. 6D), the electronic instruments (FIG. 6E), the portable communication terminals such as mobile telephones (FIG. 6F), the PCs (FIG. 6G), the PDAs (FIG. 6H), the voice recorders (FIG. 6I), or the PC cards or memory card readers (FIG. 6J) each include a card interface 220 and a slot 230 connected to the card interface 220, the memory card 100 is electrically connected to the slot 230 so as to communicate predetermined data or commands with a CPU or a microprocessor provided in an electronic circuit 210 of each of the video cameras (FIG. 6A), the TVs or IPTVs (FIG. 6B), the MP3 players (FIG. 6C), the game consoles or navigations (FIG. 6D), the electronic instruments (FIG. 6E), the portable communication terminals such as mobile telephones (FIG. 6F), the PCs (FIG. 6G), the PDAs (FIG. 6H), the voice recorders (FIG. 6I), or the PC cards or memory card readers (FIG. 6J), via the card interface 220. The card interface 220 may be one of various interface protocol such as USB, MMC, PCI-E, SATA, PATA, SCSI, ESDI, or IDE.

Also, although it is not illustrated, the memory device 100 according to the present inventive concept may be a non-volatile memory device, for example, a NAND flash memory device, that may maintain stored data even when power is discontinued, and may be used for mobile devices such as cellular phones, PDA digital cameras, portable game consoles, or MP3 players, or home applications such as HDTVs, DVDs, routers, and GPS's.

Also, the memory device according to the present inventive concept may be used for a computer system, for example, application chipsets, camera image processors (CIS's), mobile DRAMs, and solid state drives/disks (SSDs) for storing data.

As described above, the method of programming the memory device 100 according to the present inventive concept, and the memory device 100 using the method, uses the 2-step verify program operation to optimize the distribution voltage of a memory cell so that the total program operation time may be reduced.

While the inventive concept has been particularly shown and described with reference to embodiments thereof, it will be understood that various changes in form and details may be made therein without departing from the scope of the following claims.

What is claimed is:

1. A method of programming a memory device, the method comprising:
a first verify operation wherein a first verify voltage is compared with a distribution voltage of a memory cell; and
a second verify operation wherein if a result of the comparison performed in the first verify operation is pass, the distribution voltage is adjusted until the distribution voltage is higher than a second verify voltage.

2. The method of claim 1, wherein the second verify operation comprises comparing the distribution voltage and the second verify voltage while adjusting the distribution voltage to be higher than the second verify voltage.

3. The method of claim 2, further comprising:
adjusting the distribution voltage using a first program voltage if the comparison result of the first verify operation is fail, wherein the adjusting the distribution voltage is repeatedly performed until the distribution voltage is higher than the first verify voltage.

4. The method of claim 3, wherein the adjusting the distribution voltage using the first program voltage is performed according to an incremental step pulse program (ISPP) method in which the first program voltage is applied to a word line connected to the memory cell.

5. The method of claim 1, wherein the second verify operation comprises:
comparing the distribution voltage and the second verify voltage; and
adjusting the distribution voltage using a second program voltage, if a comparison result of the second verify operation is fail,
wherein the adjusting the distribution voltage is repeatedly performed until the adjusted distribution voltage is higher than the second verify voltage.

6. The method of claim 5, wherein the adjusting of the distribution voltage using the second program voltage is performed by a bit line forcing method in which the second program voltage is applied to a bit line connected to the at least one memory cell.

7. A method of programming a memory device, the method comprising:
comparing a first verify voltage and a distribution voltage of a memory cell to generate a comparison result; and
if the comparison result is fail, adjusting the distribution voltage using a first program voltage until the distribution voltage is higher than a first verify voltage, and
if the comparison result is pass, adjusting the distribution voltage using a second program voltage until the distribution voltage is higher than a second verify voltage.

8. The method of claim 7, wherein adjusting the distribution voltage using the second program voltage comprises comparing the distribution voltage and the second program voltage while adjusting the distribution voltage to be higher than the second program voltage.

9. The method of claim 8, wherein the adjusting the distribution voltage by using the second program voltage until the distribution voltage is higher than the second verify voltage is performed by a bit line forcing method in which the second program voltage is applied to a bit line connected to the at least one memory cell.

10. The method of claim 7, wherein the adjusting the distribution voltage by using the first program voltage is performed by an incremental step pulse program (ISPP) method in which the first program voltage is applied to a word line connected to the at least one memory cell.

11. A memory device comprising:
a cell array comprising a memory cell;
a comparator configured to compare at least one verify voltage and a distribution voltage of the memory cell and providing a comparison result;
a controller configured to provide a control signal in response to the comparison result; and
a voltage generator configured to provide a first program voltage and a second program voltage to the cell array in response to the control signal,
wherein the cell array adjusts the distribution voltage of the memory cell according to either the first program voltage or the second program voltage.

12. The memory device of claim 11, wherein the voltage generator is further configured to apply the first program voltage to a word line connected to the memory cell using an incremental step pulse program (ISPP) method controlled by the control signal.

13. The memory device of claim 11, wherein the voltage generator is further configured to apply the second program voltage to a bit line connected to the memory cell using a bit line forcing method as controlled by the control signal.
